(19) United States
(12) Patent Application Publication
(10) Pub. No.: US 2003/0121645 A1
(43) Pub. Date: Jul. 3, 2003

(54) Heat dissipater for a central processing unit

(76) Inventor: Tien-Lai Wang, Taoyuan Hsien (TW)

Correspondence Address: VENABLE, BAETJER, HOWARD AND CIVILETTI, LLP, P.O. BOX 34385, WASHINGTON, DC, 20043-9998, US

(21) Appl. No.: 10/028,292

(22) Filed: Dec. 28, 2001

(51) Int. Cl. F28D 15/00; H05K 7/20

(52) U.S. Cl. 165/104.26; 165/104.33; 361/700

(57) ABSTRACT

A heat dissipater for a CPU (Central Processing Unit) includes an upper plate and a lower plate abutting each other. The upper plate has a series of fins extending upwards from a first side of the upper plate and a recess defined in a second side of the upper plate. The lower plate includes a first side having a recess defined to correspond to the recess in the upper plate and forming a closed chamber with the recess in the upper plate and a second side adapted to abut the CPU. Volatile liquid is received in the closed chamber to promote the dissipating effect of the heat dissipater for a CPU. The upper and lower plates are integrally made and the only step of assembly is to securely combine the two plates together so that the manufacturing processing is simplified to save manufacturing time and cost.

### BACKGROUND OF THE INVENTION

1. Field of the Invention

The present invention relates to a heat dissipater, and more particularly to a heat dissipater for a CPU (Central Processing Unit).

2. Description of Related Art

The working temperature of CPUs corresponds to the frequency of the CPU. A high frequency causes a high working temperature. However, a high working temperature damages the electrical and electronic elements of the computer that contains the CPU. Consequently, a heat dissipater for a CPU is marketed.

With reference to FIG. 11, a conventional heat dissipater (6) for a CPU in accordance with the prior art comprises a transmission block (60) adapted to abut the CPU, a dissipating block (64) and multiple heat pipes (62). Each heat pipe (62) has two opposite ends respectively extending into the transmission block (60) and the dissipating block (64) to conduct heat to the dissipating block (64). The dissipating block (64) has a series fins (66) extending upward from one side of the dissipating block (64) to increase the surface area and the amount of heat dissipated. Each heat pipe (62) has capillary structures (not shown) formed in an inner periphery of the heat pipe (62) and contains liquid to dissipate and effectively conduct heat to the dissipating block (64).

However, new CPUs, such as the Pentium 4 manufactured by Intel, operate at a frequency greater than one giga-hertz so that the conventional heat dissipater needs to be altered to dissipate the heat generated by high-frequency CPUs. Furthermore, the transmission block (60) and the dissipating block (64) are connected by the heat pipe (62) so that a thermal resistance will be formed between the transmission block (60) and the heat pipe (62) of the heat pipe (62) and the dissipating block (64). The thermal resistance will reduce the heat dissipated by the conventional heat dissipater. At the same time, to connect the transmission block (60) and the dissipating block (64) with heat pipes (62) has many complex steps. The fabrication will take a lot of time, and the manufacturing cost is high.

The present invention has arisen to mitigate and/or obviate the disadvantages of the conventional heat dissipater for a CPU.

### SUMMARY OF THE INVENTION

The main objective of the present invention is to provide an improved heat dissipater for a CPU that has a simplified manufacturing processing and saves manufacturing time and cost.

To achieve the objective, the heat dissipater for a CPU in accordance with the present invention comprises an upper plate and a lower plate abutting each other. The upper plate has a series of fins extending upwards from a first side of the upper plate and a recess defined in a second side of the upper plate. The lower plate includes a first side having a recess defined to correspond to the recess in the upper plate and forming a closed chamber with the recess in the upper plate and a second side adapted to abut the CPU. Volatile liquid is received in the closed chamber to promote the dissipating effect of the heat dissipater for a CPU. The upper and lower plates are integrally made and the only step of assembly is to securely combine the two plates together so that the manufacturing processing is simplified to save manufacturing time and cost.

Further benefits and advantages of the present invention will become apparent after a careful reading of the detailed description with appropriate reference to the accompanying drawings.

### BRIEF DESCRIPTION OF THE DRAWINGS

FIG. 1 is a perspective view of a heat dissipater for a CPU in accordance with the present invention;

FIG. 2 is an exploded perspective view of the heat dissipater for a CPU in FIG. 1;

FIG. 3A is a side plan view in partial section of the upper plate and the lower plate in FIG. 1 showing the cross sectional shape of the capillary groove;

FIG. 3B is a side plan view in partial section of the upper plate and the lower plate in FIG. 1 showing the cross sectional shape of a second embodiment of the capillary groove;

FIG. 3C is a side plan view in partial section of the upper plate and the lower plate in FIG. 1 showing the cross sectional shape of a third embodiment of the capillary groove;

FIG. 4 is a side plan view in partial section of the heat dissipater for a CPU in FIG. 1 for showing how the liquid flowing;

FIG. 5 is a top plan view of the heat dissipater for a CPU in the FIG. 1 for showing how the air current flowing;

FIG. 6 is a perspective view of a second embodiment of the upper plate and the lower plate in FIG. 2;

FIG. 7 is a perspective view of a third embodiment of the upper plate and the lower plate in FIG. 2;

FIG. 8 is an exploded perspective view of a second embodiment of a heat dissipater for a CPU in accordance with the present invention;

FIG. 9 is a perspective view of a third embodiment of a heat dissipater for a CPU in accordance with the present invention;

FIG. 10 is perspective view of a fourth embodiment of a heat dissipater for a CPU in accordance the present invention; and

FIG. 11 is a perspective view of a conventional heat dissipater for a CPU in accordance with the prior art.

### DETAILED DESCRIPTION OF THE INVENTION

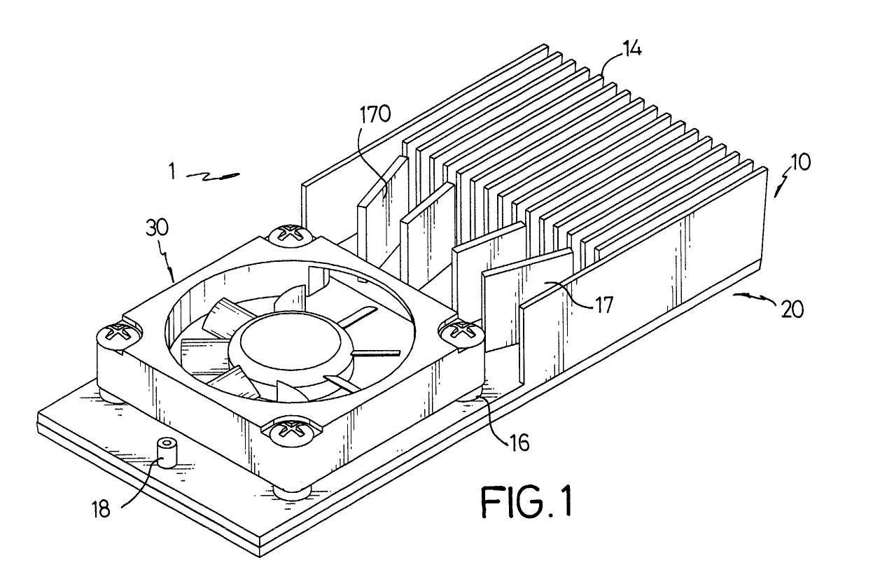

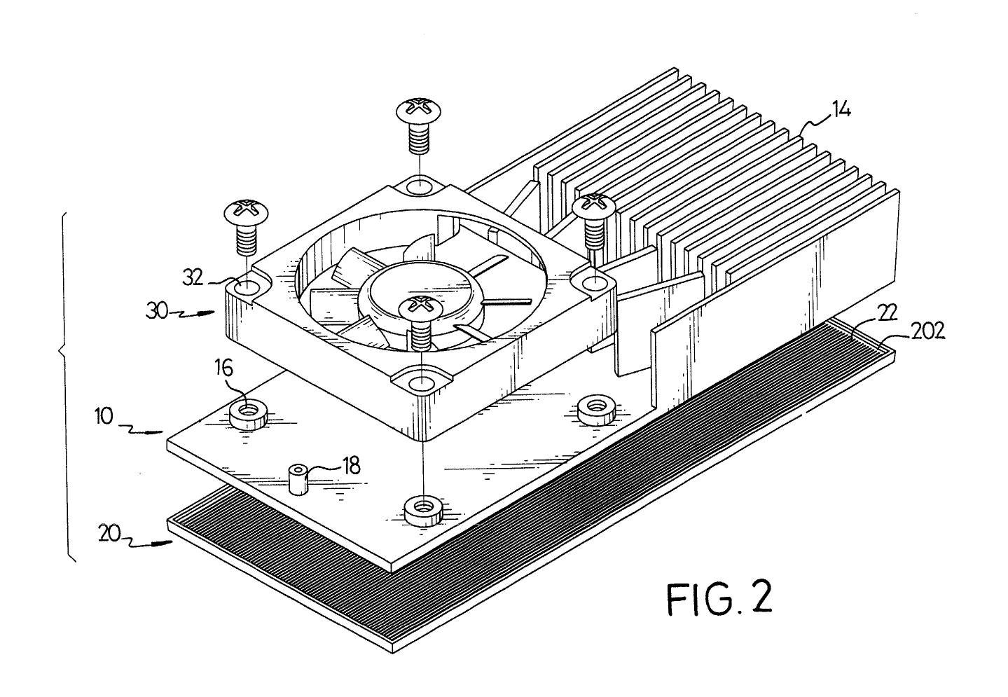

With reference to the drawings and initially to FIGS. 1, 2 and 3A, a heat dissipater (1) for a CPU (Central Processing Unit) in accordance with the present invention comprises an upper plate (10) and a lower plate (20) abutting each other and secured by a means selected from a group consisting of welding, ultrasonic wave welding or gluing. The upper plate (10) has a first side adapted for mounting a cooling fan (30) and a second side. The lower plate (20) has a first side securely abutting the second side of the upper plate and a second side adapted to abut the CPU. The upper plate (10) and the lower plate (20) are made of a good thermal conductive material, such as copper, magnesium aluminum, or an alloy of the above materials and the methods for forming the upper plate (10) and the lower plate (20) are die casting or semi-solid injection molding.

The first side of the upper plate (10) includes a first segment and a second segment. The first segment has a connecting device (16) formed to be adapted for mounting the cooling fan (30). The second segment has a series of fins (14) integrally extending upwards from the first side of the upper plate (10). In the preferred embodiment of the present invention, the connecting device (16) includes four threaded holes so that the cooling fan (30) is mounted on the first segment of the upper plate (10) by bolts (not numbered). Multiple baffles (17) are integrally and perpendicularly connected to the first side of the upper plate (10) between the cooling fan (30) and the series of the fins (14). A passage (170) is formed between adjacent baffles (17). The upper plate (10) includes a first recess (102) defined in the second side of the upper plate (10) and a series of first capillary grooves (12) defined in a bottom of the recess (102). An inlet (18) is defined in the first side of the upper plate (10) and communicates with the first recess (102) in the second side of the upper plate (10).

The lower plate (20) comprises a second recess (202) defined in the first side of the lower plate (20) and corresponding to the first recess (102) in the second side of the upper plate (10). The second recess (202) and the first recess (102) in the second side of the upper plate (10) form a closed chamber (40) after the lower plate (20) is securely attached to the second side of the upper plate (10). A series of second capillary grooves (22) are defined in a bottom of the second recess (202). Each capillary groove (22) aligns with a corresponding one of the series of first capillary grooves (12) in the first recess (102) in the second side of the upper plate (10).

The closed chamber (40) is drawn to be vacuum via the inlet (18). Then the volatile liquid, such as pure water, methanol, toluene, coolant or the like, is charged in to the closed chamber. The inlet (18) is sealed as the adequate liquid is charged into. Creating a vacuum in the chamber (40) is to prevent the non-condensable gas and contamination in the air from staying in the chamber (40). It will have an adverse influence on the performance of dissipating heat. The other reason to vacuum is that the operating temperature is often lower than the vaporized temperature at atmospheric pressure. The volume of volatile liquid depends on the operating temperature heat flux that you intend.

Heat from the heat source, such as CPU, thermally conducts through the lower plate (20) then, conducts through the volatile liquid filled evaporator capillaries thereby heating the volatile liquid until it vaporizes at the designed operating temperature then, the high temperature (thus high pressure) vapor flow adiabatically (without heat loss or gain) toward the far end which is in the lower temperature (thus low pressure). Then the heated vapor condenses and gives up its latent heat of vaporization due to fanned air current guide by multiple baffles (17). The condensed volatile liquid return to the evaporator through the capillaries of the upper and lower plate (10, 20).

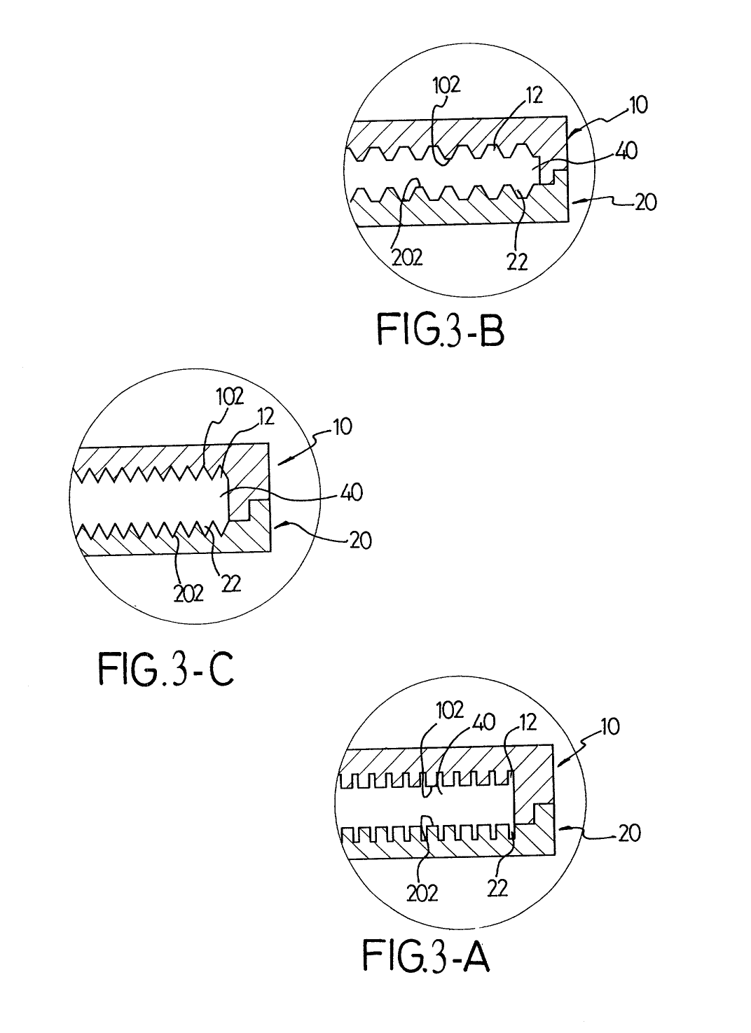

The cross sectional shape of the capillary grooves (12, 22) can be any one of several types. With reference to FIG. 3A, the cross sectional shape of the capillary grooves (12, 22) is rectangular. With reference to FIG. 3B, the cross sectional shape of the capillary grooves (12, 22) is trapezoidal. With reference to FIG. 3C, the cross sectional shape of the capillary grooves (12, 22) is triangular.

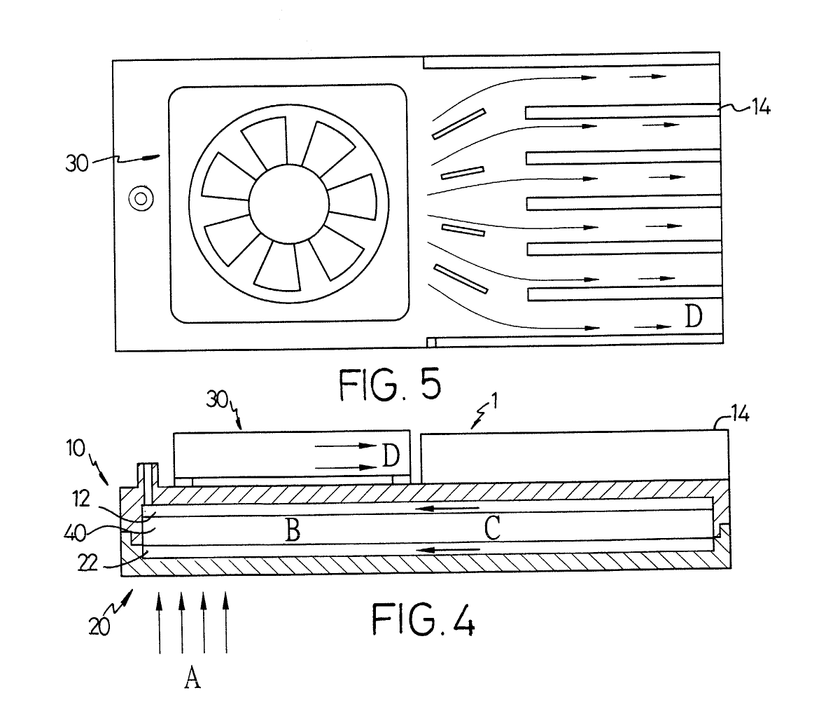

With reference to FIGS. 4 and 5, the lower plate (20) has a part of the bottom adapted to abut a heat source (A), such as a CPU, and corresponding to the cooling fan (30). The vapor-liquid balance is changed when the CPU operates and generates heat thereby raising the temperature. The liquid in the chamber (40) is vaporized due to the heat cased by the CPU and the vapor (B) of the liquid completely fills the chamber (40). The vapor (B) of the liquid condenses in the capillary grooves (12) because the cooling fan (30) generates an air current (D) that blows to the fins (14) through the passages (170) to reduce the temperature of the upper plate (10) and the lower plate (20). The condensed vapor (C) flows toward the heat source (A) and vaporizes again. By such an arrangement and circulation, the temperature of the CPU is effectively reduced by the heat dissipater when the CPU operates.

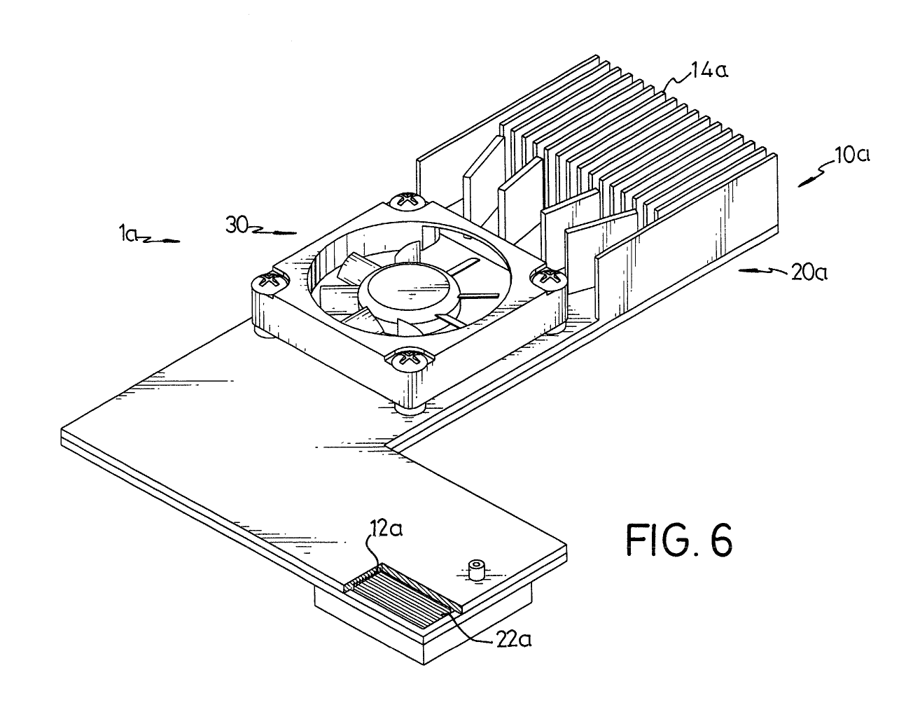

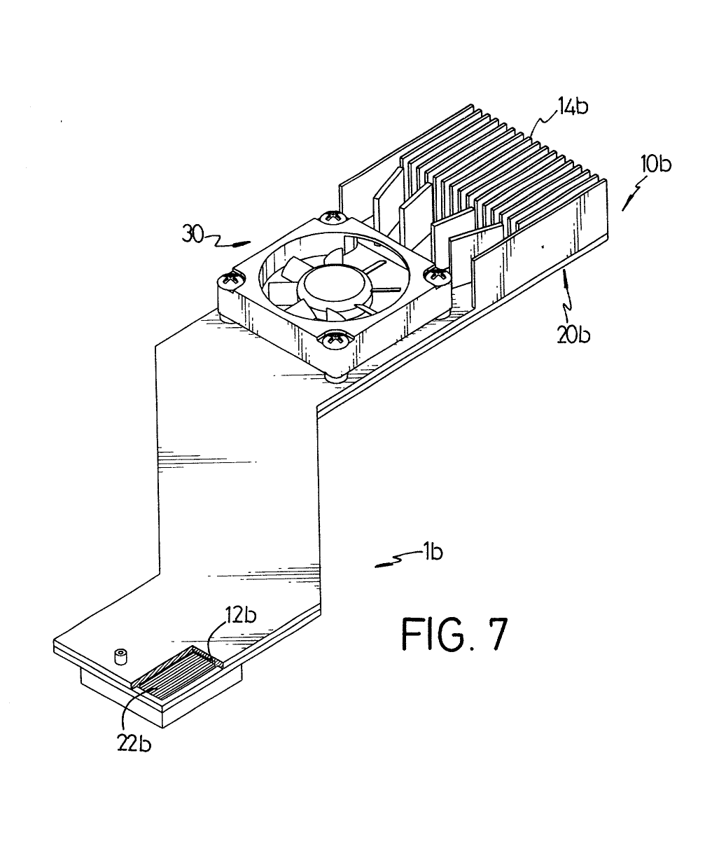

The upper plate (10) and the lower plate (20) can be any of several shapes to correspond to a circuit board or accommodate other elements. With reference to FIG. 6, the upper plate (10a) and the lower plate (20a) of the heat dissipater (1a) are L-shaped. With reference to FIG. 7, the upper plate (10b) and the lower plate (20b) of the heat dissipater (1b) have an offset or zigzag shape.

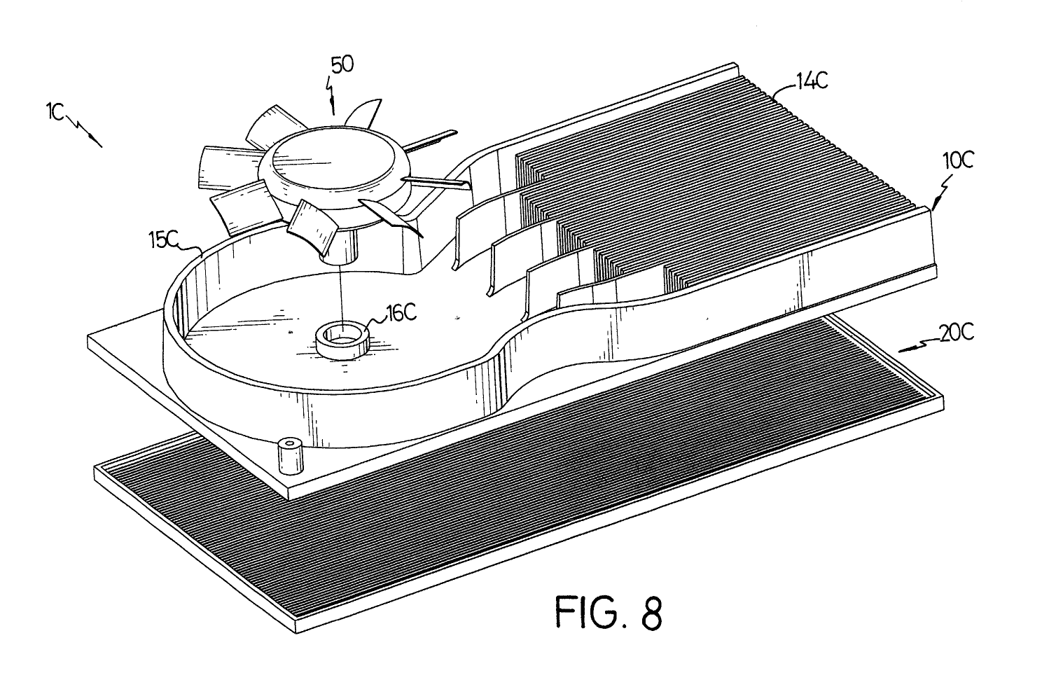

With reference to FIG. 8, a second embodiment of a heat dissipater for a CPU in accordance with the present invention has a skirt (15c) integrally extending upwards from the first side of the upper plate (10c). The skirt (15c) encompasses a frame-less cooling fan (50) with a series of fins (14c). The skirt (15c) has an opening (not numbered) to allow the air current to blow through the fins (14c). The connecting device (16c) of the fan (50) is a collar (16c) to receive a sleeve that rotatably receives a shaft (not numbered) of the cooling fan (50).

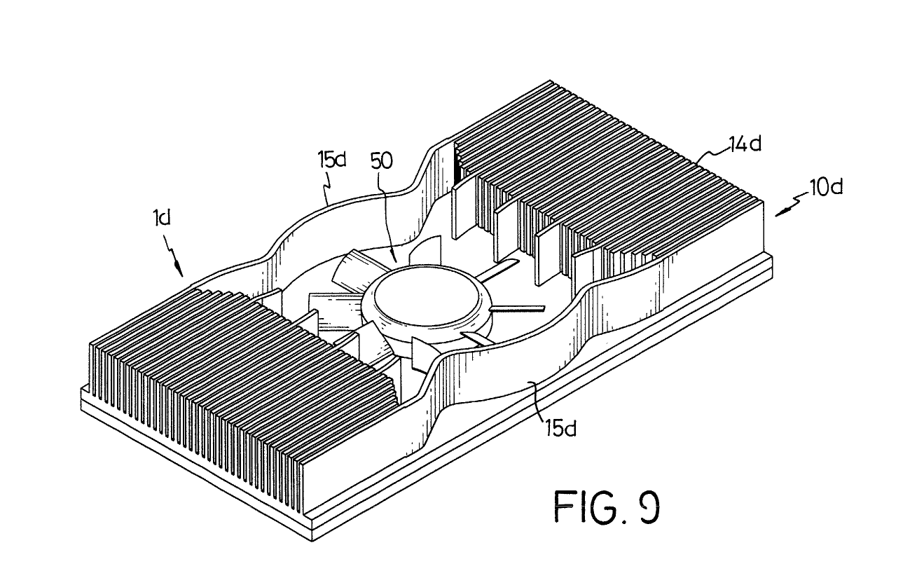

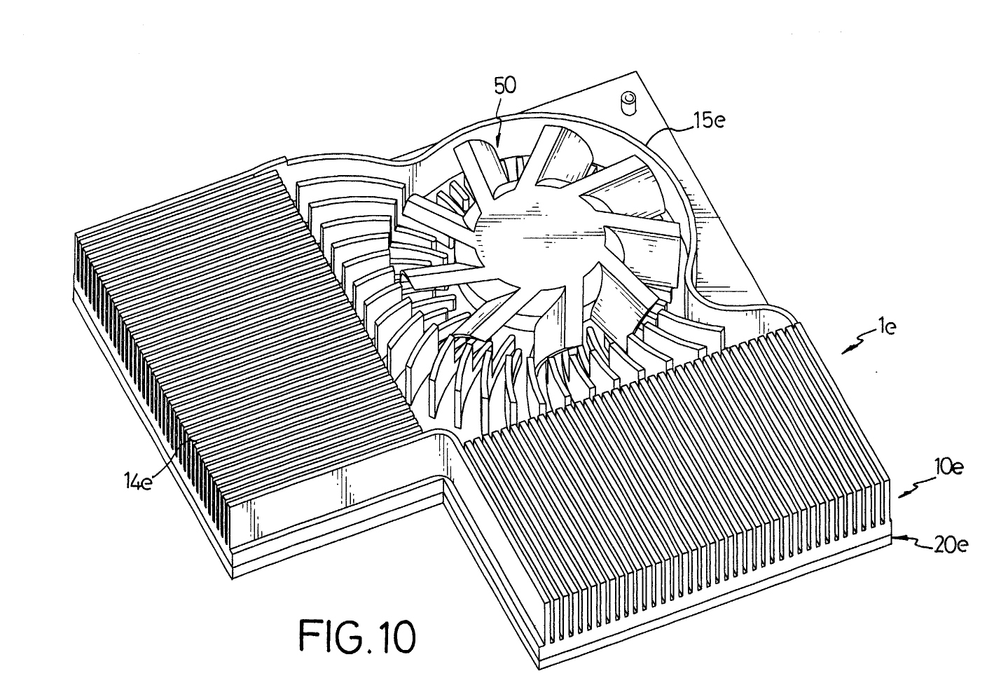

With reference to FIG. 9, a third embodiment of a heat dissipater (1d) for a CPU in accordance with the present invention has an upper plate (10d) where the first side has two opposite end segments each having a series of fins (14d) integrally extending upwards from the first side of the upper plate (10d). A frame-less cooling fan (50) is rotatably mounted on a middle segment of the upper plate (10d). Each fin (14d) is parallel to two opposite sides of the upper plate (10d). The opposite sides of the upper plate (10d) each has an skirt (15d) extending from the first side of the upper plate (10d) around the cooling fan (50) and the fins (14d).

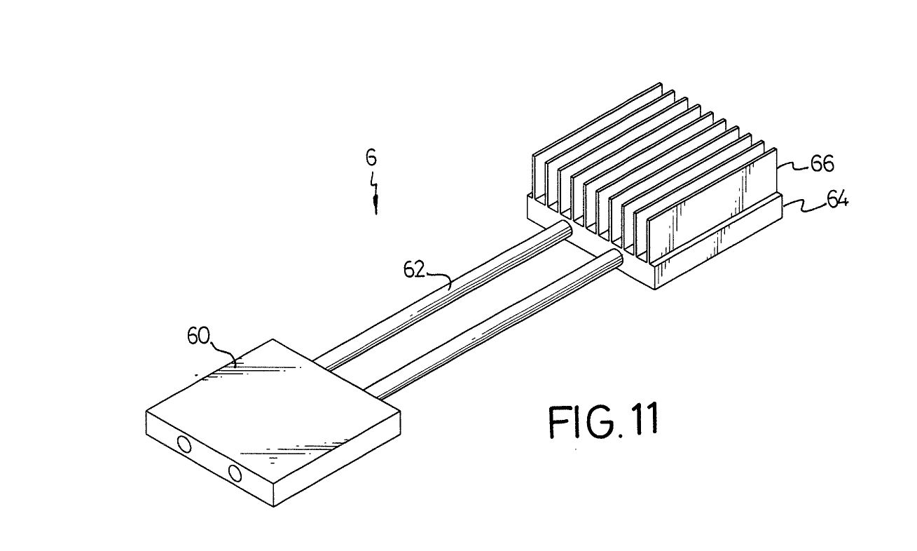

With reference to FIG. 10, a fourth embodiment of a heat dissipater (1e) for a CPU in accordance with the present invention is L-shaped. The upper plate (10e) and the lower plate (20e) are L-shaped. The first side of the upper plate (10e) includes two distal end potions each having a series of fins (14e) integrally extending upwards from the first side of the upper plate (10e) and a corner segment having a cooling fan (50a) rotatably mounted on the first side of the upper plate (10e). An L-shaped skirt (15e) integrally extends perpendicular from the first side of the upper plate (10e) around the cooling fan (50a) with the two series of fins (14e).

The liquid in the chamber (40) absorbs the heat generated by an operating CPU to reduce the temperature of the working CPU. Consequently, the dissipating effect of the heat dissipater in accordance with the present invention is more effective than that of the conventional heat dissipater. A lower working temperature can effectively lengthen the useful life of the electrical and electronic elements. The upper plate (10) and the lower plate (20) are integrally made and the only step of assembling is to securely combine the two plates (10, 20) together so that the manufacturing processing is simplified to save manufacturing time and cost.

Although the invention has been explained in relation to its preferred embodiment, it is to be understood that many other possible modifications and variations can be made without departing from the spirit and scope of the invention as hereinafter claimed.

What is claimed is:

1. In a CPU (Central Processing Unit) heat dissipater having an upper plate and a lower plate, wherein the improvements comprise:
the upper plate being integrally formed and made of a heat conductive material, the upper plate including:
fins integrally extending upwards from a first side of the upper plate to be adapted for mounting a cooling fan on the upper plate;
multiple baffles integrally extending perpendicularly from the first side of the upper plate between the cooling fan and the fins;
a passage formed between adjacent baffles so as to guide an air current generated by the cooling fan to the fins;
a first recess defined in a second side of the upper plate; and
a series of first capillary grooves defined in a periphery of the first recess in the upper plate;
the lower plate being integrally formed and made of the heat conductive material, the lower plate having a first side facing the upper plate and a second side adapted to abut the CPU, the lower plate including;
a second recess defined in the first side of the lower plate, the second recess corresponding to the first recess in the upper plate and defining a closed chamber with the first recess in the upper plate after the lower plate is securely attached to the second side of the upper plate; and
a series of second capillary grooves defined in a periphery defining the second recess in the lower plate, each second capillary groove aligning and communicating with a corresponding one of the series of first capillary grooves; and
volatile liquid received in the closed chamber, the liquid having a volume smaller than that of the chamber, the volatile liquid being able to be vaporized when a temperature of a working environment is raised.

2. The heat dissipator as claimed in claim 1, wherein a method for forming the upper and lower plates is die casting.

3. The heat dissipator as claimed in claim 1, wherein a method for forming the upper and lower plates is semi-solid injection molding.

4. The heat dissipater as claimed in claim 1, wherein the first and second grooves are horizontal relative to each other.

5. The heat dissipater for a CPU as claimed in claim 4, wherein the first and second capillary grooves each has a rectangular cross sectional shape.

6. The heat dissipater for a CPU as claimed in claim 4, wherein the first and second capillary grooves each has a trapezoidal cross sectional shape.

7. The heat dissipater for a CPU as claimed in claim 4, wherein the first and second capillary grooves each has triangular cross sectional shape.

8. The heat dissipater for a CPU as claimed in claim 3, wherein the upper plate comprises at least one skirt integrally extending perpendicular from the first side of the upper plate and adapted to around the cooling fan.

9. The heat dissipator for a CPU as claimed in claim 2, wherein the material is selected from a group consisting of copper, aluminum, magnesium or the other conductive alloys thereof.

10. In a CPU (Central Processing Unit) heat dissipater having an upper plate and a lower plate, wherein the improvements comprise:
the upper plate being integrally formed and made of a heat conductive material, the upper plate including:
fins integrally and divergently extending from a center of a first side of the upper plate to be adapted for mounting a cooling fan on the upper plate;
multiple baffles integrally extending perpendicularly from the first side of the upper plate between the cooling fan and the fins;
a passage formed between adjacent baffles so as to guide an air current generated by the cooling fan to the fins;
a first recess defined in a second side of the upper plate; and
a series of first capillary grooves defined in a periphery of the first recess in the upper plate;
the lower plate being integrally formed and made of the heat conductive material, the lower plate having a first side facing the upper plate and a second side adapted to abut the CPU, the lower plate including;
a second recess defined in the first side of the lower plate, the second recess corresponding to the first recess in the upper plate and defining a closed chamber with the first recess in the upper plate after the lower plate is securely attached to the second side of the upper plate; and
a series of second capillary grooves defined in a periphery defining the second recess in the lower plate, each second capillary groove aligning and communicating with a corresponding one of the series of first capillary grooves; and
volatile liquid received in the closed chamber, the liquid having a volume smaller than that of the chamber, the volatile liquid being able to be vaporized when a temperature of a working environment is raised.

11. The heat dissipator as claimed in claim 10, wherein a method for forming the upper and lower plates is die casting.

12. The heat dissipator as claimed in claim 10, wherein a method for forming the upper and lower plates is semi-solid injection molding.

13. The heat dissipator as claimed in claim 10, wherein the first and second grooves are horizontal relative to each other.

14. The heat dissipater for a CPU as claimed in claim 13, wherein the first and second capillary grooves each has a rectangular cross sectional shape.

15. The heat dissipater for a CPU as claimed in claim 13, wherein the first and second capillary grooves each has a trapezoidal cross sectional shape.

16. The heat dissipater for a CPU as claimed in claim 13, wherein the first and second capillary grooves each has triangular cross sectional shape.

17. The heat dissipater for a CPU as claimed in claim 13, wherein the upper plate comprises at least one skirt integrally extending perpendicular from the first side of the upper plate and adapted to around the cooling fan.

18. The heat dissipater for a CPU as claimed in claim 10, wherein the closed chamber defined between the upper and lower plates is secured by a means selected from a group consisting of welding, ultrasonic wave welding or gluing.

19. The heat dissipater for a CPU as claimed in claim 10, wherein the volatile liquid is selected from a group consisting of pure water, methylbenzene, methanol or coolant.
